(19) United States
(12) Patent Application Publication
(10) Pub. No.: US 2013/0231482 A1
(43) Pub. Date: Sep. 5, 2013

(54) Cyclometalated Au(III) Complexes Suitable for Electroluminescent Devices

(71) Applicants: Jai Anand Garg Narayana Rao, Zurich (CH); Alexander Zalan Claude Szentkuti, Horgen (CH); Koushik Venkatesan, Zurich (CH)

(72) Inventors: Jai Anand Garg Narayana Rao, Zurich (CH); Alexander Zalan Claude Szentkuti, Horgen (CH); Koushik Venkatesan, Zurich (CH)

(73) Assignee: UNIVERSITAET ZURICH PROREKTORAT MNW, Zurich (CH)

(21) Appl. No.: 13/883,596

(22) PCT Filed: Nov. 10, 2011
(86) PCT No.: PCT/EP2011/069889

§ 371 Date: May 6, 2013

(30) Foreign Application Priority Data
Nov. 10, 2010 (EP) 10190765.7

(51) Int. Cl. H01L 51/00

(52) U.S. Cl. CPC H01L 51/0084
USPC 546/4

(57) ABSTRACT

Monocyclometalated Au(III) complexes, cis-[(N̂C)AuL₁L₂] and cis-[(N̂C)Au L₁̂L₂] represented by generic chemical formulae 1a and 1b respectively with ligands L₁ and L₂ being either similar (L₁=L₂) or dissimilar (L₁≠L₂) but with at least one of either (L₁ or L₂) comprising a σ-donating carbanionic group is described here. Also described are Au(III) complexes of formula in which L₃ denotes a neutral donor ligand bound in a tridentate fashion. The complexes depicted by the formulae 1a, 1b and 1c in the present invention are suitable as emissive phosphorescent organometallic materials in OLEDs.

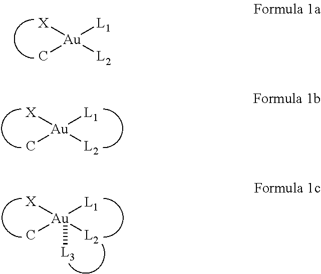

### BACKGROUND OF THE INVENTION

Electroluminescent devices based on transition metal complexes have attracted a great degree of interest, owing to their promise for improved luminescence efficiency than pure organic based light emitting devices.¹ The design and synthesis of organometallic complexes especially employing third-row transition metals like Re, Os, Ir, Pt or Au is desirable firstly, because of the larger theoretical limit of harnessing 100% of the excitons as compared to those 25% in purely organic fluorescent emitters. This is commonly called ‘triplet-harvesting’ and is mainly because of the efficient mixing of singlet and triplet energy levels by virtue of the large spin-orbit coupling shown by the heavier atoms.¹ Most of the work on exploration of electroluminescent organometallic entities are focused on Ir(III), Ru(II), and Pt(II).¹ Much of the effort is directed towards achieving emission tunability by varying the organic ligands surrounding the central metal atom and also to improve the functional aspects like the devices drive voltage, efficiency and lifetime. Gold although is sufficiently a heavier-element having a ‘spin-orbit’ coupling constant of ξ=5100 cm⁻¹ for its 5d electrons; it is generally believed that thermally accessible, low-lying metal-centered (d-d) states and the photoreactivity exhibited by these complexes would perhaps render this metal unsuitable for utilization in the device architecture. Recently, research in Yam's group²⁻⁴ has lead to the realization of gold(III) tridentate ĈN̂C ligands with at least one site for a good sigma donating ligand as a suitable embodiment for electroluminescent materials or dopants OLED which is reflected in WO patent document⁵. The inventors rationalize that by judicious choice of cyclometallating strong field ligands (σ-donating) it is possible to increase the d-d splitting energy to inaccessible heights so as to create an appropriate environment for efficient radiative triplet emission. Organogold (III) triaryl complexes with aryl carbanionic substituents are less known in literature probably owing to their facile ability for reductive elimination, except for reports from Vicente et al.^{6,7} about the synthesis of similar class of compound, there are scarce reports for these class of compounds. Also, organogold σ-alkynyl complexes are extensively investigated for their interesting luminescence, non-linear optical (NLO) properties and for building metallamacromolecular entities. In marked contrast, gold(III) alkynyl complexes are relatively scarce. Some of the notable precedent reports include, mononuclear gold(III) complexes containing one alkyne ligand [Au(C≡CCF₃)Me₂(L)], [Au(C≡CR)Me₂(PPh₃)], [Au(ĈN̂C)(C≡CR)], three alkyne ligands [Au(C≡CR)₃(L)] and four alkyne ligands [ER₄]⁺[Au(C≡CR)₄] have been reported by the groups of Schmidbaur⁸ and Yam²⁻⁴ and also a Au(I)-Au(III) dinuclear complexes bearing two alkyne ligands [Au^{I}(μ-{CH₂}PPh₂)₂Au^{III}(C≡R)₂ has been synthesized by Laguna and co-workers.⁹ Mononuclear neutral gold(III) complexes consisting of two alkynyl ligands in cis-geometry about the Au(III) centre have been recently studied.^{10,11} The invention described herein pertains to the design of the synthetic pathways for accessing closely related complexes, specific embodiments in this invention is also directed towards improving the stability of these complexes to endure vapor deposition commonly encountered during integrating these components into the device architecture.

### BRIEF SUMMARY OF THE INVENTION

1) The present invention is directed towards the method of preparation of preferably neutral organometallic embodiments comprising gold metal in its oxidation state 3+. The basic structure comprises of a cyclometallated bidentate chelating ligand (ĈX) with one carbanionic donor and ancillary ligands L₁ and L₂ which can either chelate to the metal centre in a monodentate fashion (Formula 1a) or in bidentate fashion (Formula 1b) or in tridentate fashion (Formula 1c). The ancillary ligands L₁, L₂, L₃ can be represented by the generic formulae 1a, 1b or 1c with ligands L₁ and L₂ being either identical (L₁=L₂) or different L₁≠L₂) or (L₁=L₂≠L₃) or L₁≠L₂≠L₃) but with at least one of either L₁ or L₂ comprising a σ-donating carbanionic group, and L₃ is preferably a neutral donor. Ligands, L₁, L₂ each independently, represent a group containing halogen, hydrogen, cyano, amino, nitro, aryl, alkoxy, alkynyl, heteroaryl, heteroalkynyl, alkylcarbonyl, arylcarbonyl, alkoxycarbonyl, mono- or diaminocarbonyl, heteroaryl, heteroalkynyl, alkylcarbonyloxy, arylcarbonyloxy, N-heterocyclic carbenes, borylated or silylated substituents and the like or the substituted forms of aforementioned, wherever applicable as meaningful organic entities.

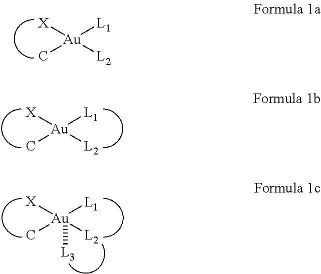

2) The cyclometallated part of the formula (1a, 1b and 1c) represented as ĈX consists of a group with an atom capable of dative bonding (X) to the metal, preferably nitrogen or carbenic C or phosphinic P or sulfur, and can independently be selected as a part of substituted or unsubstituted aromatic or heteroaromatic systems. The other part (C) being monocarbanionic ligand as a part of substituted or unsubstituted aromatic systems or substituted or unsubstituted heteroaromatic systems. Both the entities C and X are linked to each other by covalent bonding as a part of conjugated aromatic or non-aromatic systems.
3) Methods for the preparation of specific classes of embodiments which are subclasses to the main structure depicted in Formula 1a and 1b in the present invention are described separately herein as (a), (b) and (c).

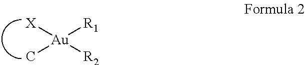

(a) In Formula 2, Ligands R₁ and R₂ are carbanionic (C⁻) substituents derived preferably from mono- or polyaromatic systems or heteroaromatic systems, formally generated by the removal of hydrogen by direct lithiation or by replacement of halogen by halogen-exchange (HALEX) reaction upon addition of strong base like n-BuLi at temperatures (−78° C. to RT). Also, aryl nucleophile equivalents formally generated by activation of aryl-CH bonds by Grignard reagents and also other main group metals like copper (Cu), Zinc (Zn), Tin (Sn), Germanium (Ge), Silicon (Si) and Sodium (Na) could be used. The reaction as exemplified below is carried out in aprotic solvents, wherein B⁻ is a base, M is gold (Au) in its oxidation state 3+, X and Y are halides preferably (Cl, Br, I).

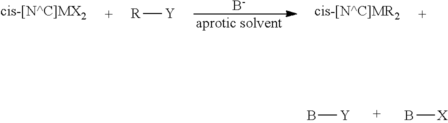

In the present invention, it pertains to mention that the preferred reactants (R—Y) being perfluorinated aromatic substituents for example pentafluorophenyl benzene or 2,4-difluorobenzene and also those bearing trifluoromethyl substituents like trifluromethyl benzene, shows significantly more stability over non-fluorinated analogues based on thermogravimetric (TGA) [see FIG. 7] analysis and are suitable for vapor deposition techniques commonly used for OLED fabrication.

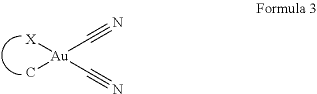

(b) The process for obtaining the products depicted in Formula 3 comprises of reacting 1 mole of the monocyclometallated dihalide complex [N̂C]Au(III)X₂ with slight excess over stoichiometric equivalent (more than 2 moles) of alkali metal cyanides like NaCN or KCN or [NBu₄] [CN] under ambient or thermal-conditions.

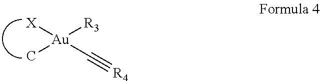

(c) The process for the obtaining the products depicted in Formulae 4 comprises of reacting 1 mole of the monocyclometalated monohalide complex cis-[N̂C]Au(III)R₁X with a slight excess over stoichiometric equivalents of silver acetylides or the reaction is carried out in basic pH-conditions which is achieved using sec- or tert-alkylamine for example triethylamine for deprotonation and copper(I) salts are used as promoters in organic solvents at temperatures ranging from 0° C. to ambient in presence of the respective terminal alkynes.
4) The Au(III) complexes of the generic formulae cis-[(N̂AC)AuL₁L₂] and cis-[(N̂C)AuL₁̂L₂], described in the present invention exhibit room temperature phosphorescence both in fluid media and also in rigidified glass matrices at 77 K, and are suitable as phosphorescent emitters or dopants fabricated into OLEDs to generate electroluminescence.
5) The present invention will be illustrated more specifically by non-limiting examples, it being understood that the changes and variation can be made therein without deviating from the scope and the spirit of the invention herein claimed.

### LIST OF DRAWINGS

The above mentioned and other features and objects of this invention and the manner of achieving them will become more apparent and this invention itself will be better understood by reference to the following description of various embodiments of this invention taken in conjunction with the accompanying drawings, wherein the Compound numbering corresponds to that given in the following Scheme I:

Preferred Embodiments actually studied described under preparation method (a)

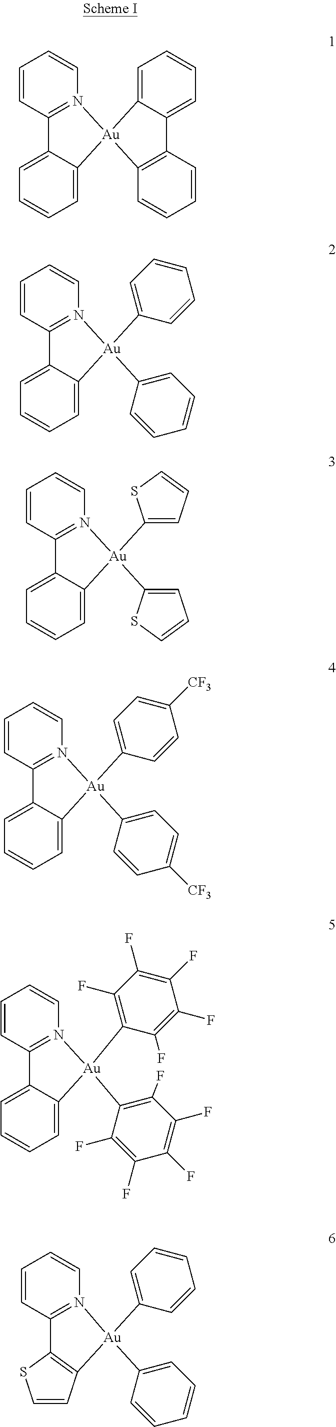

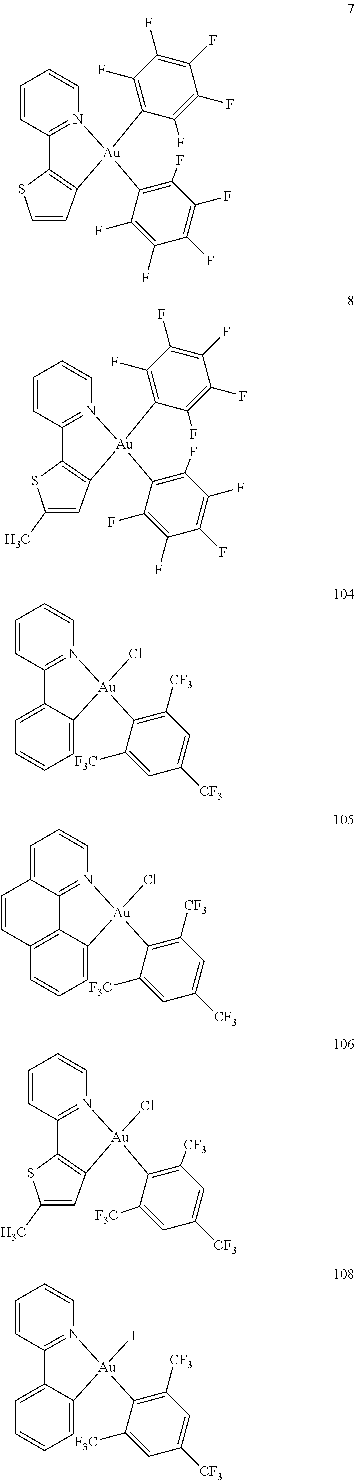

FIG. 1 Electronic absorption and normalized emission (I) spectra of Compound 1 dot (. . . .), Compound 2 dash (- - - -), Compound 3 solid (-) in degassed CH₂Cl₂ at 298 K

FIG. 2. Electronic absorption and normalized emission (I) spectra of Compound 4 solid (-) Compound 5 dash (- - - -) in degassed CH₂Cl₂ at 298 K.

FIG. 3 Electronic absorption and normalized emission (I) spectra of Compound 6 dot (. . . .), Compound 7 dash (- - - -), Compound 8 solid (-) in degassed CH₂Cl₂ at 298 K

FIG. 4 Electronic absorption and normalized emission (I) spectra of Compound 101 solid (-), Compound 102 dash (- - - -), Compound 103 dot (. . . .) in degassed CH₂Cl₂ at 298 K

FIG. 5 Electronic absorption and normalized emission (I) spectra of Compound 104 solid (-), Compound 105 dot (. . . .), Compound 106 dash (- - - -) in degassed CH₂Cl₂ at 298 K.

FIG. 6 Electronic absorption and normalized emission (I) spectra of Compound 107 dash dot (-.-.-.-.), Compound 108 solid (-), Compound 109 dash (- - - -), Compound 110 dot (. . . .) in degassed CH₂Cl₂ at 298 K

FIG. 7. Thermal gravimetric traces of the complexes measured under N₂ atmosphere, rate of heating 1° C./min from 25° C. to 600° C. * denotes instrumental artefact.

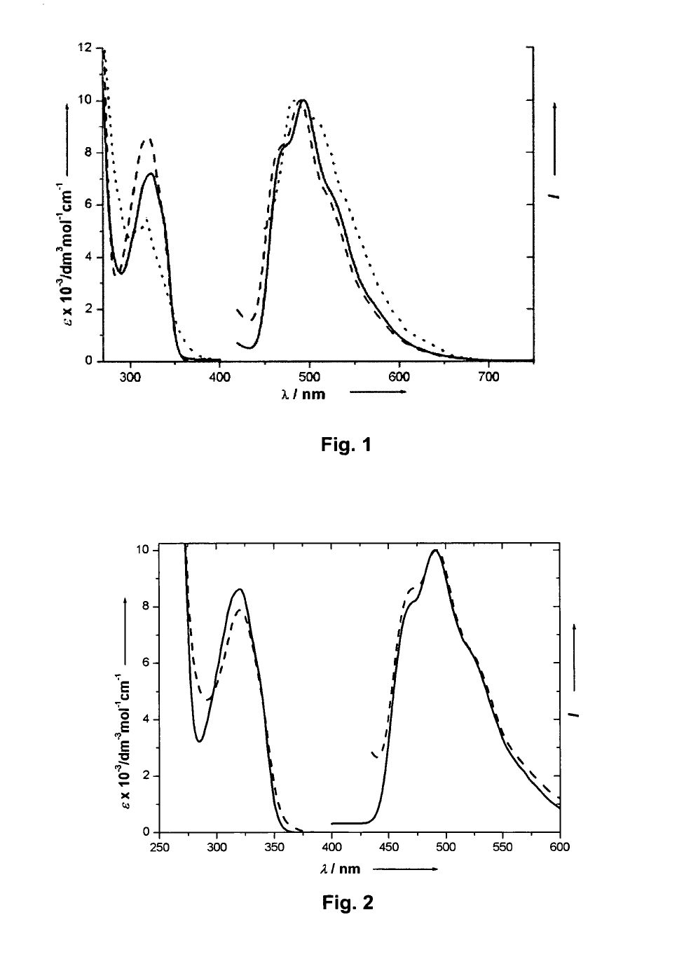

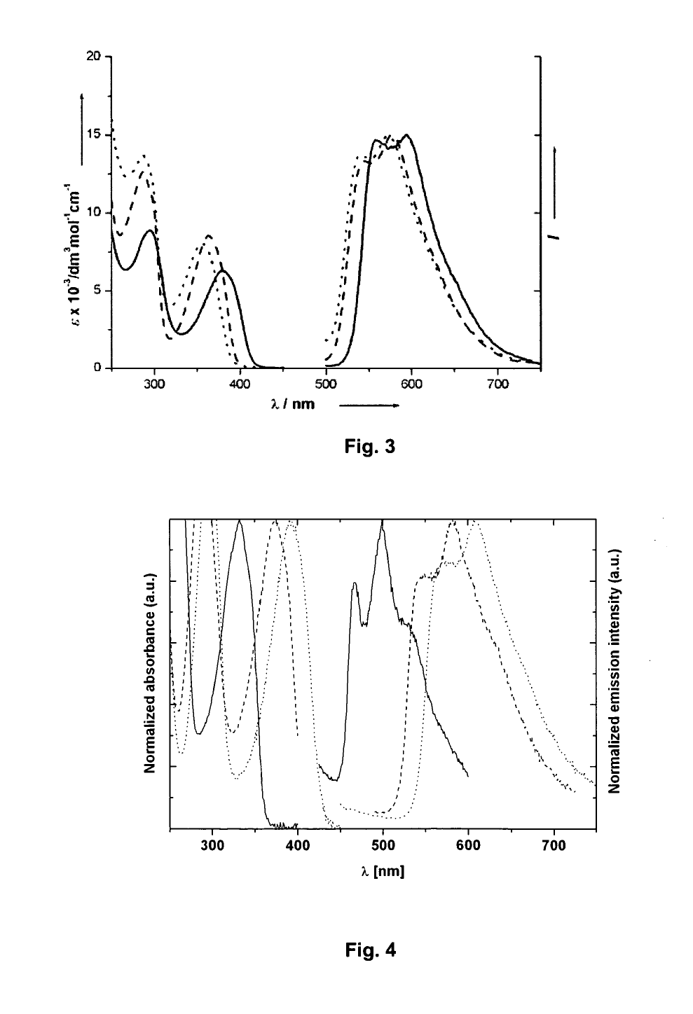

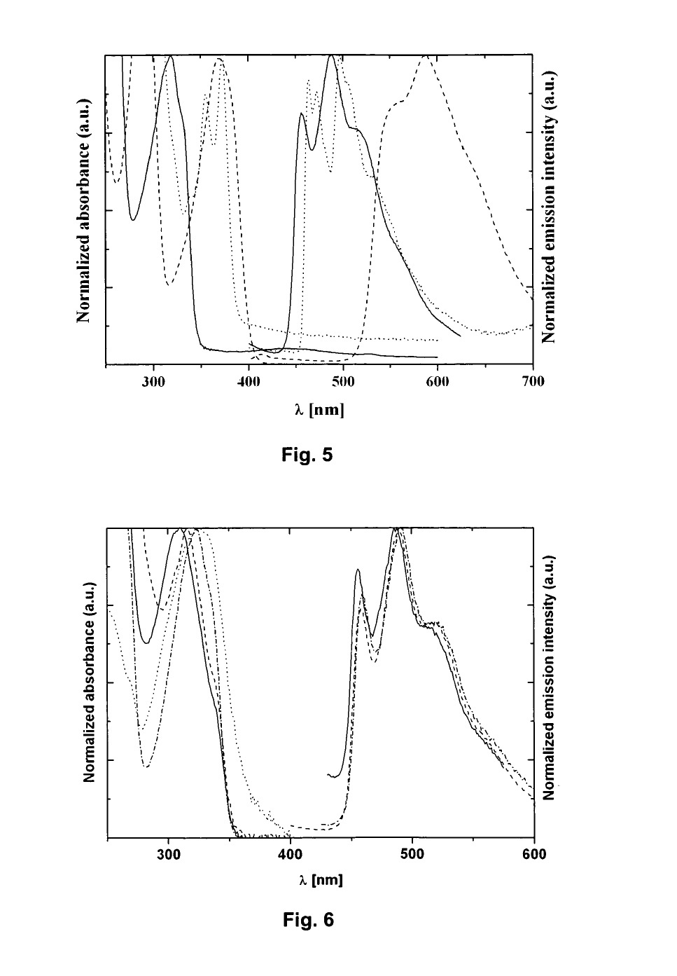

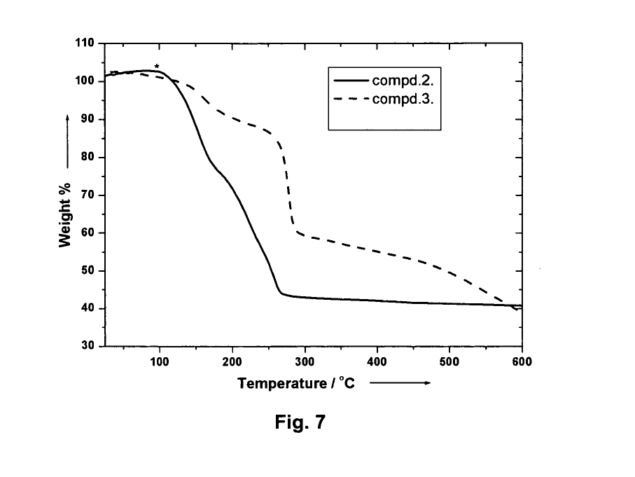

Any person with ordinary skill can imagine the immediate extension of the preferred core as given below.

### EXAMPLES OF GENERIC VARIATION IN CYCLOMETALLATING CORE (ĈX)

In the following Scheme II there are given examples of generic variations in the cyclometallating core, wherein X═S, O, NR; and wherein R₁, R₂, R₃, R_{4,} R_{5,} R₆, R₇ and R₈ are each independently selected from hydrogen, halogen, alkyl, aryl and arylene; and wherein R′₁ and R′₂, may, in combination, be aryl, and wherein n, m, o, p, q are dependently or independently belonging to aromatic conjugated systems with carbon atoms extending more than unity.

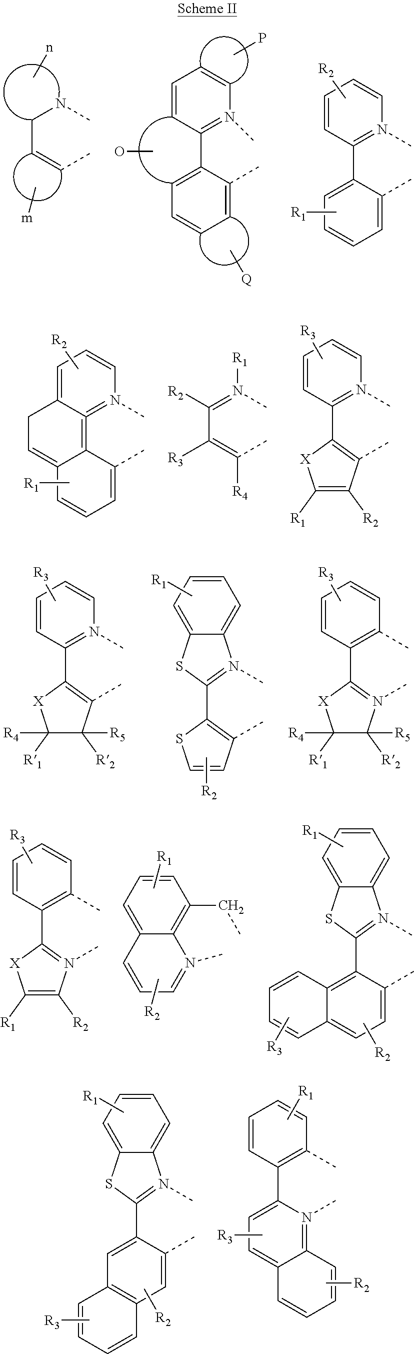

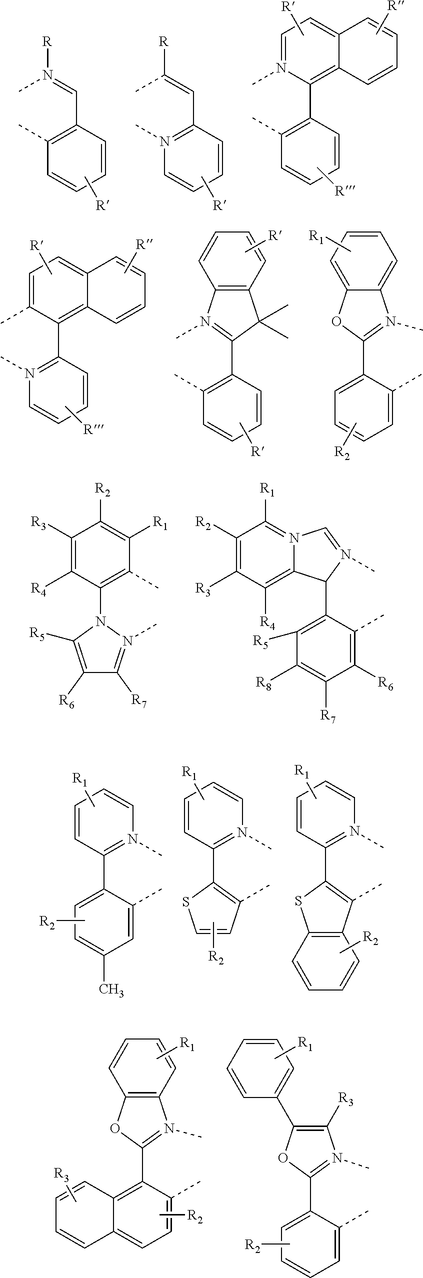

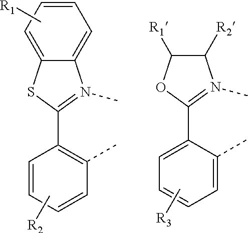

### EXAMPLES OF GENERIC VARIATION IN THE ANCILLARY LIGANDS: (L₁ AND L₂)

Generic Variations of L₁ and L₂ as Monodentate Ligands in Formula 1a

In the following Scheme IIIa there are given examples of generic variations of L₁ and L₂ as monodentate ligands in formula 1a

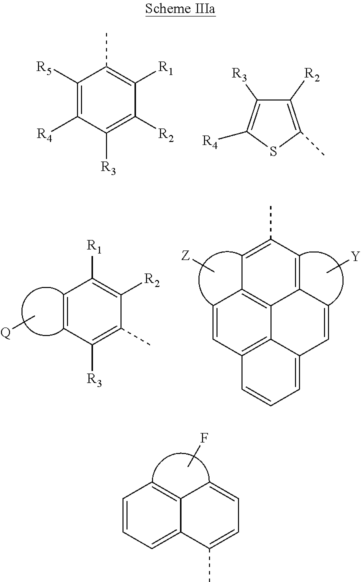

wherein, as understood earlier, ligands L₁ and L₂ are preferably identical entities, but also either L₁ or L₂ can be halogens (Cl, Br, I, F), CN, SCN, NCS, NC, CNO, N-heterocyclic carbene, and NCO. The substituents R₁, R₂, R₃, R₄, R₅ can be halogen, hydrogen, cyano, amino, nitro, aryl, alkoxy, alkynyl, heteroaryl, heteroalkynyl, alkylcarbonyl, arylcarbonyl, alkoxycarbonyl, mono- or diaminocarbonyl, heteroaryl, heteroalkynyl, alkylcarbonyloxy, arylcarbonyloxy and borylated or silylated substituents the like or the substituted forms of aforementioned, wherever applicable as meaningful organic entities:

Generic Variations of L₁ and L₂ as Bidentate Ligands as in Formula 1b

In the following Scheme IIIb there are given examples of generic variations of L₁ and L₂ as bidentate ligands in formula 1b, wherein X═S, O, NR; Y═S, O, NR, R₁, R₂, R₃, R_{4,} and R₅ are independently, hydrogen halogen, alkyl, aryl or arylene; R′₁ and R′₂ may, in combination, be aryl. n, m, o, p, q are dependently or independently belonging to aromatic conjugated systems with carbons atoms extending more than unity:

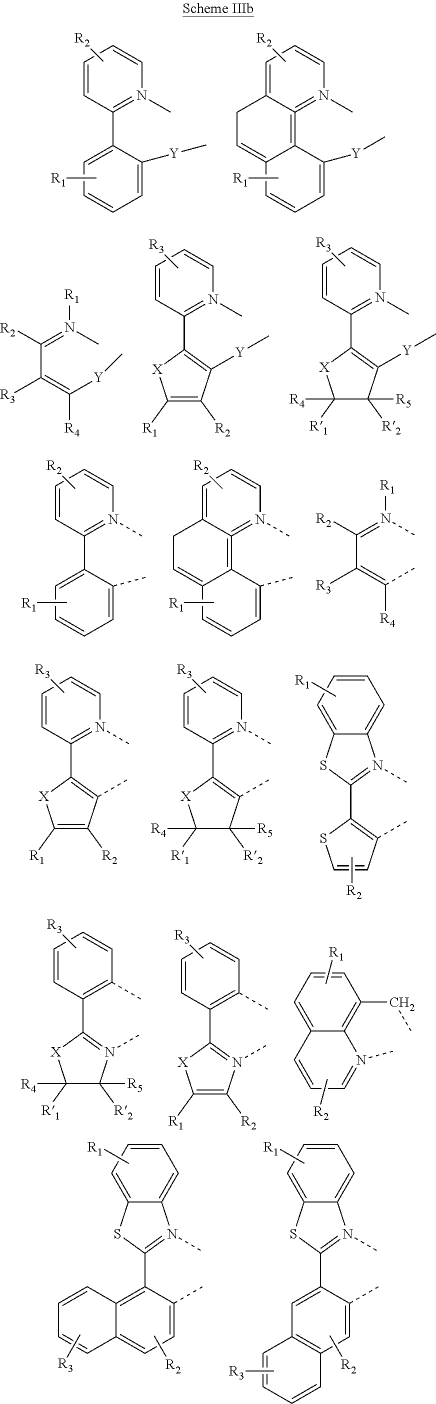

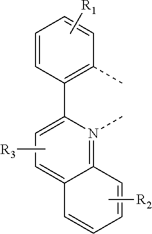

Generic Variations of L₁ L₂ L₃ as Tridentate Ligands as in Formula 1c

In the following Scheme IIIc there are given examples of generic variations of L₁, L₂ and L₃ as tridentate ligands in formula 1c

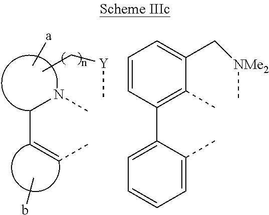

wherein Y═S, O, NR, n>0, a, b are dependently or independently belonging to aromatic conjugated systems with carbons atoms extending more than unity.

### Preferred Embodiments Actually Studied Described Under Preparation Method (b)

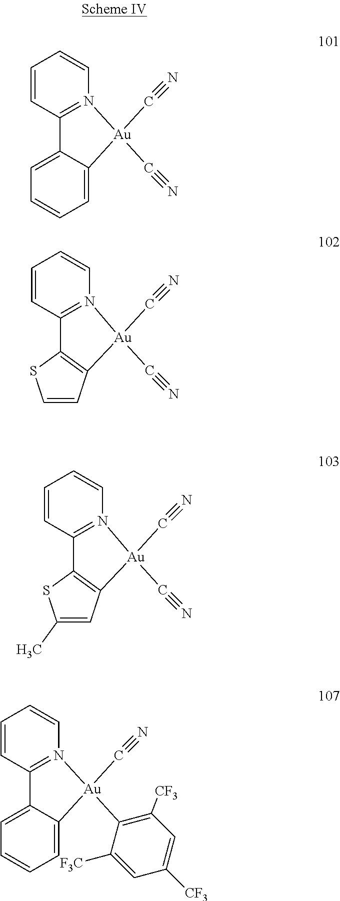

### Preferred Embodiments Actually Studied Described Under Preparation Method (b)

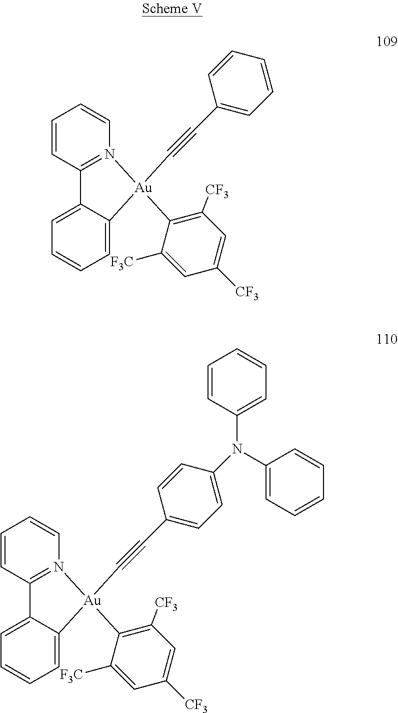

### Synthesis and Characterization

cis-[(N̂C)AuL] [N̂C=2-phenylpyridine, L=2,2′-biphenyl] (1): To 2,2′-Dibromobiphenyl (88.0 mg, 0.28 mmol) in dry diethylether (5.0 mL), n-BuLi (0.35 mL, 0.55 mmol, 1.6 M in hexanes) was added slowly via syringe at −78° C. and then stirred for 1 h at RT. The dilithiated solution was then transferred into a flask containing diethylether suspension of A (100.0 mg, 0.23 mmol) and AgOTf (4.6 mg, 0.018 mmol) maintained at -78° C. The cold bath was removed immediately after addition and the mixture was allowed to stir for 10 h. It was then quenched by addition of water (5.0 mL) and extracted with dichloromethane (2×15 mL). The separated organic layers were combined and dried over MgSO₄. Filtration followed by concentration of the solvent in vacuo gave the crude product as light brown solid. It was washed with pentane (5.0 mL) and the residue was purified by flash column chromatography using silica gel (eluent: Hexane/EtOAc=3/2) to afford 1 as off-white solid. Single crystals suitable for X-ray diffraction analysis were obtained from slow evaporation by layering of pentane over concentrated solution of the complex in dichloromethane at 0-5° C. Yield=15.0 mg, 12%. IR: (KBr) vₘₐₓ 3414, 2924, 2853, 1638, 1618, 1605, 1581, 1482, 1429, 1160, 1104, 1013, 736, 734, 726, 615, 479 cm⁻¹; ¹H-NMR (500 MHz, CD₂Cl₂, 298 K): δ=7.11 (td, J=6.0, 1.0 Hz, 1H), 7.18-7.25 (m, 3H), 7.36 (td, J=6.5, 1.0 Hz, 1H), 7.50-7.57 (m, 4H), 7.62 (d, J=6.5 Hz, 1H), 7.92 (d, J=8.5 Hz, 1H), 7.95 (d, J=8.5 Hz, 1H), 8.08 (d, J=6.5 Hz, 2H), 8.19 (d, J=7.0 Hz, 1H), 9.2 (d, J=5.5 Hz, 1H);¹³C{¹H} NMR (125 MHz, CD₂Cl₂, 298 K): δ=121.1, 121.3, 121.7, 123.8, 125.0, 126.5, 126.9, 127.0, 127.1,127.5, 131.1, 132.0, 134.0, 135.7, 140.7, 147.3, 148.5, 149.4, 154.0, 155.8, 167.3, 171.4, 174.1; elemental analysis (%) calc for C₂₃H₁₆AuN; C, 54.88; H, 3.20; N, 2.78; Found: C, 54.60; H, 3.12; N, 2.68 (Note: ¹H NMR and IR analyses of late eluting fractions from the column (eluent: ethyl acetate) suggest the presence of ca 10% of mono-coordinated biphenyl Au(III) chloride complex, characterization details of which is not presented here).

General procedure for the synthesis of cyclometalated Au (III) complexes (2-8): n-BuLi (0.52 mmol, 1.6 M in hexanes) was added via syringe to a cooled (−78° C.) solution of the aryl halide (0.50 mmol) in dry diethylether under nitrogen atmosphere and stirred for 20 minutes at that temperature. It was then transferred via cannula into a flask containing an diethylether suspension of cycloaurated Au(III)dichloride (0.22 mmol) precooled at −78° C. This temperature was maintained for 20 min and then the mixture was allowed to warm to RT and stirred further for 1 h. (Note: At this stage the reaction mixture turns dark (violet colouration), more in the case of non-fluorinated analogues indicating partial decomposition of the product to metallic gold). TLC examination (EtOAc/Hexane=1/5) of the reaction mixture at this stage usually showed two major spots, the first (R_{f}˜0.7) corresponding to the homocoupled diaryl and the second being the desired organometallic product (R_{f}˜0.4) which also gets faintly illuminated in UV lamp longwave (365 nm). The reaction was quenched by addition of water (5 mL) followed by extraction with ethyl acetate/dichloromethane. After separation, the organic layer was dried over MgSO₄ and concentrated in vacuo to obtain the crude product. Purification on a short silica gel column (eluent: EtOAc and hexane mixture) was adopted to obtain analytically pure products. Some derivatives were prepared with modifications in the general procedure and are described individually.

[(N̂C)AuL₂] [N̂C=2-phenylpyridine, L =C₆H₅] (2): Phenyl lithium (0.61 mL, 0.746 mmol, 1.8 M soln. in di-n-butylether) was syringed into a schlenk flask containing cooled (−78° C.) suspension of A (150.0 mg, 0.35 mmol) in diethylether (5.0 mL) under N₂ atmosphere. The cold bath was removed 15 min after addition and the reaction mixture was allowed to warm up to RT and stirred for 12 h. The reaction was then quenched by adding H₂O (8.0 mL) and extracted with dichloromethane (2×10 mL). The combined dichloromethane layers were dried over MgSO₄, filtered, and concentrated in vacuo to yield the crude product. Further purification by flash column chromatography using silica gel (eluent: Hexane/EtOAc=3/1) afforded 2 as off-white solid. Single crystals suitable for X-ray diffraction analysis were obtained from slow evaporation by layering of pentane over concentrated solution of the complex in dichloromethane at 0-5° C. Yield =100.0 mg, 55.0%. IR (KBO: v.3413, 2924, 2853, 1638, 1618, 1605, 1571, 1478, 1422, 1163, 1062, 1019, 751, 734, 695, 631, 471 cm⁻¹;

¹H NMR (500 MHz, CDCl₃, 298 K): δ=7.03-7.09 (3H, m), 7.15 (t, J=8.0 Hz, 2H), 7.19 (t, J=7.0 Hz, 1H), 7.22-7.31 (m, 4H), 7.45 (d, J=8.0 Hz, 2H), 7.49 (d, J=7.0 Hz, 2H), 7.80 (d, J=7.5 Hz, 1H), 7.92-7.98 (m, 2H), 8.18 (d, J=5 Hz, 1H); ¹³C{¹H}NMR (125 MHz, CDCl₃, 298 K): δ=119.9, 123.1, 124.1, 124.6, 126.2, 127.1, 127.2, 128.7, 131.1, 132.4, 135.2, 135.9, 140.1, 142.0, 145.8, 149.2, 166.7, 166.9, 169.6; elemental analysis (%) calc for C₂₃H₁₈AuN; C, 54.66; H, 3.59; N, 2.77; Found: C, 54.52; H, 3.42; N, 2.80.

[(N^{A}C)AuL₂] [N̂C=2-phenylpyridine, L=C₆F₅] (3): This reaction was performed according to the general procedure. To Iodopentafluorobenzene (153.2 mg, 0.521 mmol) in diethylether (5.0 mL), n-BuLi (0.33 mL, 0.541 mmol, 1.6 M soln. in hexanes) was added. The lithiated product was transferred to a flask containing A (100.0 mg, 0.237 mmol) in diethylether. The crude product thus obtained after work-up was purified by flash column chromatography using silica gel (eluent: Hexane/EtOAc=5/1) to obtain off-white solid. The solid was further recrystallized from a mixture of ether and pentane to obtain 3 as white solid. Yield=66 mg, 40%. IR (KBr): vₘₐₓ 3414, 2923, 2853, 1738, 1637, 1610, 1509, 1462, 1477, 1365, 1309, 1263, 1073, 967, 906, 885, 812, 785, 757, 732, 629, 466 cm⁻¹; ¹H NMR (500 MHz, CDCl₃, 298 K): δ=6.83 (d, J=7.5 Hz, 1H), 7.29 (td, J=6.5, 1.5 Hz, 1H), 7.37 (t, J=7.0 Hz, 2H), 7.78 (d, J=7.5 Hz, 1H), 8.04 (d, J=8.0 Hz, 1H), 8.12 (td, J=8.0, 1.5 Hz, 1H), 8.25 (d, J=8.0 Hz, 1H); ¹³C{¹H} NMR (125 MHz, CDCl₃, b 298 K): δ=120.8, 124.3, 125.2, 127.8, 132.3, 133.8, 137.5 (dm, ¹J_{C—F}=251.0 Hz), 138.1 (dm, ¹J_{C—F}=251.0 Hz), 139.5 (dm, ¹J_{C—F}=251.0 Hz), 141.8, 144.1 (dm, ¹J_{C—F}=232.0 Hz), 145.1, 146.5 (dm, ¹J_{C—F}=232.0 Hz), 149.3, 158.0, 165.8, 166.7, (note : resonances for 2C submerged in baseline); ¹⁹F NMR (470 MHz, CDCl₃, 298 K): δ=−122.2 (m, 2F, o-C₆F₅), -122.3 (m, 2F, o-C₆F₅), −157.8 (t, J=20.2 Hz, 1F, p-C₆F₅), −158.7 (t, J=20.2 Hz, 1F, p-C₆F₅), −161.5 (t, J=19.2 Hz, 2F, m-C₆F₅), −162.5 (t, J=19.7 Hz, 2F, m-C₆F₅); elemental analysis (%) calc. for: C₂₄H₁ₗAuF₁₀N: C, 41.16; H, 1.58; N, 2.00; Found: C, 41.86; H, 2.00; N, 1.97.

[(N̂C)AuL₂] [N̂C=2-phenylpyridine, L=C₆H₅CF₃-p] (4): This reaction was performed according to the general procedure. To 1-bromo-4-(trifluoromethyl)benzene (117.2 mg, 0.521 mmol) in diethylether (5.0 mL), n-BuLi (0.33 mL, 0.541 mmol, 1.6 M soln. in hexanes) was added. The lithiated product was then transferred to a flask containing A (100.0 mg, 0.237 mmol) in diethylether. The crude product thus obtained after work-up was purified by flash column chromatography using silica gel (eluent: Hexane/EtOAc=5/1) to obtain 4 as off-white solid. Single crystals suitable for X-ray diffraction analysis were obtained from slow evaporation by layering of pentane over concentrated solution of the complex in dichloromethane at 0-5° C. Yield=51.0 mg, 33%. IR (KBr): vₘₐₓ 3413, 3064, 1637, 1607, 1482, 1439, 1390, 1327, 1157, 1120, 1087, 1078, 1066, 1050, 1013, 906, 820, 755, 733, 679, 666, 648, 599, 478 cm⁻¹; ¹H NMR (500 MHz, CD₂Cl₂, 298 K): δ=6.89 (dd, J=8.5, 1.5 Hz, 1H), 7.23-7.30 (m, 3H), 7.41 (d, J=8.5 Hz, 2H), 7.48 (d, J=8 Hz, 2H), 7.60 (d, J=9.0 Hz, 2H), 7.66 (d, J=8.5 Hz, 2H), 7.82 (dd, J=8.5, 1.5 Hz, 1H), 7.99-8.03 (m, 2H), 8.05 (d, J=8.0 Hz, 1H); ¹³C{¹H}NMR (125 MHz, CD₂Cl₂, 298 K): δ=120.7, 121.9, 123.9, 124.0, 124.8, 125.2, 125.3 (q, ²J_{C—F}=3.8 Hz), 125.6 (q, ²J_{C—F}=3.9 Hz), 126.5 (q, ¹J_{C—F}=32.0 Hz), 127.2 (q, =31.6 Hz), 131.5, 133.0, 135.7, 135.8, 141.3, 146.2, 147.0, 149.5, 167.0, 167.1, 172.4; ¹⁹F NMR (376 MHz, CDCl₃, 298 K): δ=−62.19 (s, 3H), −62.22 (s, 3H); elemental analysis (%) calc for: C, 46.82; H, 2.51; N, 2.18 Found: C, 46.70; H, 2.65; N, 2.18.

[(N̂C)AuL₂] [N̂C=2-phenylpyridine, L=C₄H₃S] (5): This reaction was performed according to the general procedure. To 2-bromothiophene (0.83 mL, 0.52 mmol) in diethylether (5.0 mL), n-BuLi (0.33 mL, 0.541 mmol, 1.6 M soln. in hexanes) was added and this mixture was transferred to flask containing A (100.0 mg, 0.237 mmol) in diethylether. The crude product thus obtained after work-up was purified by column chromatography on silica gel (eluent: Hexane/EtOAc=5/1) to obtain 5 as off-white solid. Single crystals suitable for X-ray diffraction analysis were obtained from slow evaporation by layering of pentane over concentrated solution of the complex in dichloromethane at 0-5° C. Yield=68 mg, 55%. IR (KBr): vₘₐₓ 3413, 1638, 1617, 1481, 1437, 1402, 1259, 1202, 1064, 1028, 834, 806, 751, 690, 626, 471 cm⁻¹; ¹H NMR (500 MHz, CDCl₃, 298 K): δ=6.98 (d, J=5.0 Hz, 1H), 7.04 (d, J=5.0 Hz, 1H), 7.12-7.14 (m, 1H), 7.16-7.18 (m, 1H), 7.24-7.28 (m, 2H), 7.29-7.32 (m, 2H), 7.47 (d, J=5.0 Hz, 1H), 7.61 (d, J=5.0 Hz, 1H), 7.75-7.77 (m, 1H), 7.95-8.00 (m, 2H), 8.35 (d, J=5.0 Hz, 1H); ¹³C{H}NMR (125 MHz, CDCl₃, 298 K): δ=119.9, 123.4, 124.3, 125.0, 125.6, 127.9, 129.4, 131.5, 132.3, 135.3, 140.8, 145.5, 149.4, 151.7, 158.7, 160.3, 163.2, 164.7, 166.8; elemental analysis (%) calc for C₁₉H₁₄AuNS₂: C, 44.10; H, 2.73; N, 2.71; Found: C, 43.90; H, 2.87; N, 2.63.

[(N̂C)AuL₂] [N̂C=2-(2-thienyl)pyridine, L=C₆H₅] (6): Phenyllithium (0.64 mL, 0.780 mmol, 1.8 M soln. in di-n-butyl ether) was slowly syringed into a schlenk flask containing cooled (−78° C.) suspension of B (100.0 mg, 0.233 mmol) in diethylether (5.0 mL) under N₂ atmosphere. The cold bath was removed after 15 min and the reaction mixture was allowed to warm up to RT and stirred further for 1 h. H₂O (8.0 mL) was added to quench the reaction mixture and was then extracted with ethyl acetate (20.0 mL). The organic layer was dried over MgSO₄, filtered and concentrated in vacuo to obtain the crude product. It was washed with pentane (2×2.0 mL) and the residue was then extracted by adding toluene (2×5.0 mL). The toluene layer was concentrated and further recrystallization of the residue with diethylether and pentane mixture (2:1) and storing at −30° C. afforded 6 as a light green solid. Single crystals suitable for X-ray diffraction analysis were obtained from slow evaporation by layering of pentane over concentrated solution of the complex in dichloromethane at 0-5° C. Yield=30.0 mg, 25%. ¹H NMR (500 MHz, CD₂Cl₂, 298 K): δ=6.71 (d, J=4.5 Hz, 1H),7.06-7.12 (m, 3H), 7.16 (t, J=7.5 Hz, 2H), 7.26 (t, J=7.5 Hz, 2H), 7.43-7.46 (m, 3H), 7.50 (d, J=7.5 Hz, 2H), 7.64 (d, J=7.5 Hz, 1H) 7.90 (td, J=8.0, 1.5 Hz, 1H), 7.97 (d, J=5.5 Hz, 1H); ¹³C{¹H}NMR (125 MHz, CD₂Cl₂, 298 K): δ=119.0, 121.4, 124.5, 125.0, 128.5, 128.7, 129.0, 133.1, 134.1, 135.0, 136.3, 140.9, 147.0, 148.8, 161.0, 164.1, 178.9; elemental analysis (%) calculated for C₂₁H₁₆AuNS: C, 49.32; H, 3.15; N, 2.74; Found: C, 49.17; H, 3.00; N, 2.80.

[(N̂C)AuL₂] [N̂C=2-(2-thienyl)pyridine, L=C₆F₅] (7): This reaction was performed according to the general procedure. To iodopentafluorobenzene (151.0 mg, 0.514 mmol) in diethylether (5.0 mL), n-BuLi (0.33 mL, 0.537 mmol, 1.6 M soln. in hexanes) was added and this was transferred to a flask containing B (100.0 mg, 0.233 mmol) in diethylether. The crude product thus obtained was purified by flash column chromatography using silica gel (eluent: Hexane/EtOAc=5/1) to obtain 7 as light yellow solid. Single crystals suitable for X-ray diffraction analysis were obtained from slow evaporation by layering of pentane over concentrated solution of the complex in diethylether at 0-5° C. Yield=61 mg, 38%. IR (KBr): vₘₐₓ 3414, 2923, 2853, 1738, 1637, 1610, 1509, 1477, 1462, 1365, 1309, 1263, 1163, 1073, 967, 906, 885, 812, 785, 757, 732, 629, 466 cm⁻¹; ¹H NMR (500 MHz, CDCl₃, 298 K): δ=6.55 (d, J=4.5 Hz, 1H), 7.24 (td, J=4.5, 1.5 Hz, 1H), 7.47 (d, J=5 Hz, 1H), 7.67 (d, J=8 Hz, 1H), 8.02 (td, J=6.5, 1.5 Hz, 1H), 8.07 (d, J=5.5 Hz, 1H); ¹³C{H} NMR (125 MHz, CDCl₃, 298 K): δ=119.7, 122.5, 130.2, 132.0, 137.5 (dm, ¹J_{C—F}=251.0 Hz), 138.0 (dm, ¹J_{C—F}=251.0 Hz), 139.5 (dm, ¹J_{C—F}=251.0 Hz), 142.4, 145.6 (dm, ¹J_{C—F}=250.0 Hz), 146.0, 146.5 (dm, ¹J_{C—F}=250.0 Hz), 149.0, 161.1, 162.4, (note : resonances for 3C submerged in baseline); ¹⁹F NMR (376 MHz, CDCl₃, 298 K): δ=−120.5 (m, 2F, o-C₆F₅), −120.6 (m, 2F, o-C₆F₅), −156.0 (t, ³J_{F—F}=18.8 Hz, 1F, p-C₆F₅), −156.9 (t, ³J_{F—F}=18.6 Hz, 1F, p-C₆F₅), −160.1 (t, ³J_{F—F}=18.8 Hz, 2F, m-C₆F₅), −161.2 (t, ³J_{F—F}=19.1 Hz, 2F, m-C₆F₅); elemental analysis (%) calc for C₂₁H₆AuF₁₀NS: C, 36.49; H, 0.87; N, 2.03; Found: C, 36.77; H, 0.89; N, 1.97.

[N̂C=2-(5-methyl-2-thienyl)pyridine, L=C₆F₅] (8): This reaction was performed according to the general procedure. To iodopentafluorobenzene (146.3 mg, 0.497 mmol) in diethylether (5.0 mL), n-BuLi (0.33 mL, 0.537 mmol, 1.6 M soln. in hexanes) was added and this mixture was transferred to flask containing C (100.0 mg, 0.226 mmol) in diethylether. The crude product thus obtained after work-up was purified by flash column chromatography using silica gel (eluent Hexane/EtOAc=5:1) to obtain 8 as yellow-green solid. Yield=90 mg, 56%. Alternatively, direct recrystallization of the crude product using ether and pentane mixture also afforded analytically pure compound. Single crystals suitable for X-ray diffraction analysis were obtained from slow evaporation by layering of pentane over concentrated solution of the complex in diethylether at 0-5° C. IR (KBr): vₘₐₓ 3413, 2925, 2027, 1637, 1615, 1508, 1463, 1477, 1366, 1264, 1250, 1160, 1072, 967, 880, 842, 812, 789, 765, 620, 473 cm⁻¹; ¹H NMR (500 MHz, CD₂Cl₂, 298 K): δ=2.49 (d, J=1.0 Hz, 3H), 6.19 (d, J=1.0 Hz, 1H), 7.13 (td, J=6.0, 1.5 Hz, 1H), 7.52 (dd, J=6.0, 1.5 Hz, 1H), 7.95 (td, J=6.0, 1.5 Hz, 1H), 7.97 (dd, J=6.0,1.5 Hz, 1H); ¹³C{¹H}NMR (125 MHz, CD₂Cl₂, 298 K): δ=15.4, 119.6, 122.2, 130.6, 137.5 (dm, ¹J_{C—F}=251.6 Hz), 138.0 (dm, ¹J_{C—F}=251.0 Hz), 140.0 (dm, ¹J_{C—F}=251.0 Hz), 143.0, 143.8, 145.0 (dm, ¹J_{C—F}=251.0 Hz), 147.0, 147.1 (dm, ¹J_{C—F}=251.0 Hz), 148.0 (dm, ¹J_{C—F}=251.0 Hz), 149.0, 161.4, 163.0, (note: resonances for 2C submerged in baseline); ¹⁹F NMR (376 MHz, CDCl₃, 298 K): δ=−120.5 (m, 2F, o-C₆F₅), −120.6 (m, 2F, o-C₆F₅), −156.2 (t, ³J_{F—F}=18.8 Hz, 1F, p-C₆F₅), −157.1 (t, ³J_{F—F}=21.5 Hz, 1F, p-C₆F₅), −160.20 (t, ³J_{F—F}=18.8 Hz, 2F, m-C₆F₅), −161.21 (t, ³J_{F—F}=22.5 Hz, 2F, m-C₆F₅); elemental analysis (%) calc for C₂₂H₈AuF₁₀NS: C, 37.46; H, 1.14; N, 1.99; Found: C, 37.63; H, 1.27; N, 2.06.

cis-1(N̂C)AuL₂] [N̂C=2-phenylpyridine (ppy), L=CN⁻] (101). A solution of [NBu₄]CN (64 mg, 0.237 mmol) in MeOH (5 mL) under N₂ atmosphere was added to a Schlenk containing the cis-[(ppy)AuCl₂] (40 mg, 0.095 mmol) diluted in MeCN (5 mL). The grey reaction mixture was stirred for 4 h at r.t. Then the reaction was quenched with water (50 mL), washed with a saturated NaCl-solution (50 mL) and extracted with DCM (2×50 ml). The organic layer was dried over Na₂SO₄, filtered and the solvent was evaporated under reduced pressure, to give the crude product as a brownish solid. The residue was purified by column chromatography on silica gel (eluent: dichloromethane/Ethylacetate=1/1) to afford a white solid of the title compound. A toluene (3×5 mL) wash was done for final purification. Single crystals suitable for X-ray diffraction analysis were obtained from slow evaporation by layering of pentane over concentrated solution of the complex in dichloromethane at 0-5° C. Yield =22.6 mg, n=0.056 mmol, 59%. ¹H NMR (500 MHz, DMSO-d₆, 298 K): δ 7.43 (t, J=7.5 Hz, 1H), 7.49 (t, J=8 Hz, 1H), 7.76 (dd, J=4 and 9.5 Hz, 1H), 7.84 (d, J=8 Hz, 1H), 8.04 (d, J=6.5 Hz, 1H), 8.40 (d, J=4 Hz, 2H), 9.15 (d, J=6 Hz, 1H); ¹³C {¹H}NMR (125 MHz, DMSO-d₆, 298 K): δ 105.15 (N—Au—CN), 121.83, 126.14, 126.40, 128.84, 132.20, 135.36, 139.11 (C—Au—CN), 143.72, 145.28, 149.36, 151.58, 164.89; elemental analysis (%) calcd for: C₁₃H₈AuN₃: C, 38.73; H, 2.00; N, 10.42 Found: C, 38.55; H, 2.08; N, 10.36.

cis-[(N̂C)AuL₂] [N̂C=2-(2-thienyl)pyridine) (thpy), L=CN] (102). A solution of [NBu₄]CN (56 mg, 0.210 mmol) in MeOH (5 mL) under N₂ atmosphere was added to a Young-Schlenk containing the cis-[(thpy)AuCl₂] (30 mg, 0.070 mmol) diluted in MeCN (5 mL). The green reaction mixture was stirred for 48 h at r.t. Then the reaction was quenched with water (50 mL), washed with a saturated NaCl-solution (50 mL) and extracted with DCM (2×50 mL). The organic layer was dried over Na₂SO₄, filtered and the solvent was evaporated under reduced pressure, to give the crude product as a yellow/brown solid. The residue was purified by column chromatography on silica gel (eluent: dichloromethane/ethylacetate=1/1) to afford a yellow solid of the title compound. Single crystals suitable for X-ray diffraction analysis were obtained from slow evaporation by layering of pentane over concentrated solution of the complex in DCM at 0-5° C. Yield=11.8 mg, n=0.029 mmol, 41%. ¹H NMR (500 MHz, DMSO-d₆, 298 K): δ7.29 (d, J=4.5 Hz, 1H), 7.59 (t, J=6 Hz, 1H), 7.94 (d, J=4.5 Hz, 1H), 7.98 (d, J=8 Hz, 1H), 8.30 (t, J=7.5 Hz, 1H), 8.98 (d, J=5.5 Hz, 1H); ¹³C {¹H}NMR (125 MHz, DMSO-d₆, 298 K): δ 97.79 (N—Au—CN), 120.61, 124.41, 131.51, 131.62, 135.17 (C—Au—CN), 144.39, 145.23, 148.99, 151.57, 158.77.

cis-[(N̂C)AuL₂] [N̂C=2-(5-Methyl-2-thienyl)pyridine) (5m-thpy), L=CN] (103). A solution of [NBu₄]CN (76 mg, 0.283 mmol) in dichloromethane (5 mL) under N₂ atmosphere was added to a Schlenk containing the cis-[(5 m-thpy)AuCl₂] (50 mg, 0.113 mmol) diluted in DCM (5 mL). The black reaction mixture was stirred for 24 h. Then the reaction was quenched with H₂O (50 mL), washed with a saturated NaCl-solution (50 mL) and extracted with DCM (2×50 ml). The organic layer was dried over Na₂SO₄, filtered and the solvent was evaporated under reduced pressure, to give the crude product as a brownish solid. The residue was purified by column chromatography on silica gel (eluent: ethylacetate with 1% of methanol) to afford a yellow solid of the title compound. Single crystals suitable for X-ray diffraction analysis were obtained from slow evaporation by layering of pentane over concentrated solution of the complex in dichloromethane at 0-5° C. Yield=19.9 mg, n=0.047 mmol, 41%

¹H NMR (500 MHz, DMSO-d₆, 298 K); δ 2.42 (s, 3H), 7.05 (s, 1H), 7.54 (t, J=7 Hz, 1H), 7.83 (d, J=8 Hz, 1H), 8.26 (t, J=8 Hz, 1H), 8.94 (d, J=6 Hz, 1H). cis-1(N̂C)AuL(Cl)] [NAC=2-phenylpyridine (ppy), L=C₆H₃(CF₃)₃ (Fmes)] (104). To a Schlenk flask containing Fmes (0.53 mL, 2.843 mmol) in dry DE (10 mL) under N₂ atmosphere, n-BuLi (1.75 mL, 2.80 mmol, 1.6 M in hexanes) was added slowly via syringe at ambient temperature. After the addition the reaction mixture was stirred for 2 h at r.t. The lithiated solution was then transferred into a Young-Schlenk under N₂ atmosphere containing a DE (10 mL) suspension of the cis-[(ppy)AuCl₂] (0.200 g, 0.474 mmol). The reaction was performed at 45° C. for 24 h. The reaction was then quenched with H₂O (100 mL), washed with a saturated NaCl-solution (100 mL) and extracted with DCM (2×100 mL). The organic layer was dried over Na₂SO₄, filtered and the solvent was removed under reduced pressure, to give the crude product as a yellowish solid. The residue was purified by column chromatography on silica gel (eluent: DCM/HA=1/1) afforded a yellow solid of the title compound. Single crystals suitable for X-ray diffraction analysis were obtained from slow evaporation by layering of pentane over concentrated solution of the complex in DCM at 0-5° C. Yield=246.1 mg, 0.369 mmol, 77%. ¹H NMR (500 MHz, CD₂Cl₂, 298 K): δ 6.32 (d, J=8 Hz, 1H), 7.08 (t, J=8 Hz, 1H), 7.35 (t, J=7.5 Hz, 1H), 7.60 (t, J=7.5 Hz, 1H), 7.74 (d, J=8 Hz, 1H), 8.00 (d, J=8 Hz, 1H), 8.14 (d, J=7.5 Hz, 1H), 8.17 (s, 2H), 9.51-9.52 (d, J=5 Hz, 1H); ¹³C {¹H}NMR (125 MHz, CD₂Cl₂, 298 K): δ 120.8, 124.7, 125.7, 127.8, 128.5, 132. 3, 133.6, 142.7, 143.0, 148.0, 148.4, 163.8. ¹⁹F NMR (376 MHz, CD₂Cl₂, 298 K): δ −64.83 (s,3F, p-CF₃), −61.51 (s,6F, o-CF₃); elemental analysis (%) calcd for: C₂₀H₁₀AuClF₉N: C, 35.98; H, 1.51; N, 2.10; Found: 35.67 C; 1.68 H ; 2.14 N.

cis-[(N̂C)AuL(Cl)] [N̂C=benzo[h]quinoline (bqu), L=C₆H₃(CF₃)₃ (Fmes)] (105). To a Schlenk flask containing Fmes (0.084 mL, 0.448 mmol) in dry DE (10 mL) under N₂ atmosphere, n-BuLi (0.28 mL, 0.448 mmol, 1.6 M in hexanes) was added slowly via syringe at ambient temperature. The reaction was stirred for 2 h at room temperature after the addition. The lithiated solution was added to a Young-Schlenk under N₂ atmosphere containing a DE (10 mL) suspension of the cis-[(bqu)AuCl₂] (0.050 g, 0.112 mmol). The reaction mixture was then heated up to 45° C. for 24 h, resulting in a brownish suspension. The reaction was then quenched with H₂O (50 mL), washed with a saturated NaCl-solution (50 mL) and extracted with DCM (2×50 mL). The organic layer was dried over Na₂SO₄, filtered and the solvent was concentrated under reduced pressure, to give the crude product as a white solid. The residue was purified by column chromatography on silica gel (eluent: DCM/HA=1/1) afforded a yellow solid of the title compound. Single crystals suitable for X-ray diffraction analysis were obtained from slow evaporation by layering of pentane over concentrated solution of the complex in DCM at 0-5° C. Yield=24.8 mg, 0.036 mmol, 32%. ¹H NMR (500 MHz, CD₂Cl₂, 298 K): δ (ppm)=6.55 (d, J=7.5 Hz, 1H), 7.43 (t, J=7.5 Hz, 1H), 7.83 (t, J=9 Hz, 1H), 7.86 (d, J=8 Hz, 1H), 7.92 (t, J=5.5 Hz, 1H), 7.95 (d, J=8.5 Hz, 1H), 8.22 (s, 2H), 8.63-8.65 (d, J=8 Hz, 1H), 9.70 (d, J=5 Hz, 1H); ¹³C {¹H}NMR (125 MHz, CD₂Cl₂, 298 K): δ 123.50, 123.68, 124.08, 124.94, 127.04, 127.97, 128.79, 129.70, 130.11, 131.02, 131.27, 135.19, 135.50, 138.59, 141.37, 142.68, 146.88, 147.96, 153.43; ¹⁹F NMR (376 MHz, CD₂Cl₂, 298 K): δ −61.38 (s,6F, o-CF₃), −64.82 (s,3F, p-CF₃); elemental analysis (%) calcd for: C₂₂H₁₀AuClF₉N: C, 38.20; H, 1.46; N, 2.02; Found: C, 38.07; H, 1.37; N, 1.97.

cis-[(N̂C)AuL(Cl)] [NAC=2-(5-Methyl-2-thienyl)pyridine) (5m-thpy), L =C₆H₃(CF₃)₃ (Fmes)] (106). To a Schlenk flask containing Fmes (0.19 mL, 1.00 mmol) in dry DE (20 mL) under N₂ atmosphere, n-BuLi (0.63 mL, 1.00 mmol, 1.6 M in hexanes) was added slowly via syringe at ambient temperature. The reaction was stirred for 2 h at room temperature after the addition. The lithiated solution was added to a Young-Schlenk under N₂ atmosphere containing a DE (20 mL) suspension of the cis-[(5m-thpy)AuCl₂] (0.110 g, 0.250 mmol). The reaction mixture was then heated up to 45° C. for 24 h, resulting in a black suspension. The reaction was then quenched with H₂O (100 mL), washed with a saturated NaCl-solution (100 mL) and extracted with DCM (2×100 mL). The organic layer was dried over Na₂SO₄, filtered and the solvent was concentrated under reduced pressure, to give the crude product as a brownish solid. The residue was purified by column chromatography on silica gel (eluent: DCM/HA=1/1) afforded a yellow solid of the title compound. Single crystals suitable for X-ray diffraction analysis were obtained from slow evaporation by layering of pentane over concentrated solution of the complex in DCM at 0-5° C. Yield=42.7 mg, 0.062 mmol, 24%. ¹H NMR (500 MHz, CD₂Cl₂, 298 K): δ (ppm)=2.42 (s, 3H), 5.75 (s, 1H), 7.38 (t, J=6 Hz, 1H), 7.49 (d, J=8 Hz, 1H), 7.99 (t, J=8 Hz, 1H), 8.16 (s, 1H), 9.23 (d, 6 Hz, 1H); ¹³C {¹H}NMR (125 MHz, CD₂Cl₂, 298 K): δ 15.87, 119.15, 121.98, 123.43, 123.71, 127.42, 128.34, 129.78, 135.57, 137.69, 139.53, 142.85, 145.67, 147.68, 147.96, 159.08; ¹⁹F NMR (376 MHz, CD₂Cl₂, 298 K): δ −61.67 (s,6F, o-CF₃), −64.84 (s,3F,p-CF₃); elemental analysis (%) calcd for: C₁₉H₁₀AuClF₉NS: C, 33.18; H, 1.47; N, 2.04; Found: C, 32.82 ; H, 1.54 ; N, 1.89.

cis-[(N̂C)AuL₂[NAC=2-phenylpyridine (ppy), L=C₆H₂(CF₃)₃(Fmes), CN⁻] (107). The reaction was performed under dry conditions and N₂ atmosphere. The cis-[(N̂C)Au(Fmes)(Cl)] (30 mg, 0.045 mmol) was added to a Schlenk flask containing a solution of [NBu₄]CN (13.2 mg, 0.045 mmol) in DCM (5 mL). The reaction was stirred at ambient temperature for 6.5 h. The reaction was quenched with H₂O (50 mL), washed with a saturated NaCl-solution (50 mL) and extracted with DCM (2×50 mL). The organic layer was dried over Na₂SO₄, filtered and the solvent was concentrated under reduced pressure, to give the crude product as an orange solid. The residue was purified by flash column chromatography on silica gel (eluent: HA/DCM=1/6) afforded a white solid of the title compound. Single crystals suitable for X-ray diffraction analysis were obtained from slow evaporation by layering of pentane over concentrated solution of the complex in DCM at 0-5° C. Yield=27.3 mg, 0.041 mmol, 92%. ¹H-NMR (500 MHz, CD₂Cl₂, 298 K): δ 6.32 (d, J=8 Hz, 1H), 7.08 (t, J=8 Hz, 1H), 7.35 (t, J=7.5 Hz, 1H), 7.60 (t, J=6.5 Hz, 1H), 7.74 (d, J=6.5 Hz, 1H), 8.00 (d, J=8 Hz, 1H), 8.14(d, J=7.5 Hz, 1H), 8.18 (s, 2H), 9.51 (d, J=5 Hz, 1H); ¹³C {¹H}NMR (125 MHz, CD₂Cl₂, 298 K): δ 120.7, 124.7, 125.7, 127.7, 128.4, 129.6, 132.2, 133.5, 134.7, 142.7, 142.9, 144.0, 148.0, 148.3, 163.8, 206.8 (Au—CN). ¹⁹F NMR (376 MHz, CD₂Cl₂, 298 K): δ −64.84 (s,3F, p-CF₃), −61.51 (s,6F, o-CF₃); elemental analysis (%) calcd for: C₂₁H₁₀AuF₉N₂: C, 38.32; H, 1.53; N, 4.26; Found: C, 38.13; H, 1.60; N, 4.17.

cis-1(N̂C)AuL(I)] [N̂C=2-phenylpyridine (ppy), L=C₆H₃(CF₃)₃ (Fmes)] (108). To a 100 ml Young-Schlenk under N₂ atmosphere containing a yellow solution of [(N̂C)Au(Fmes)(Cl)] (100 mg, 0.150 mmol) dissolved in ACE (10 mL), equipped with stir bar, NaI (45 mg, 0.299 mmol) was added. The reaction was stirred for 24 h at 40° C. The reaction was quenched with water (50 mL), washed with a saturated NaCl-solution (50 mL) and extracted with DCM (2×50 mL). The organic layer was dried with MgSO₄, filtered and the solvent was concentrated under reduced pressure, to give the crude product as an yellowish solid. The residue was purified by column chromatography on silica gel (eluent: HA/DCM=0.75/1) to afford a white solid of the title compound. Single crystals suitable for X-ray diffraction analysis were obtained from slow evaporation by layering of pentane over concentrated solution of the complex in DCM at 0-5° C. Yield=72.7 mg, 0.096 mmol, 63%.

¹H-NMR (376 MHz, CD₂Cl₂, 298 K): δ 6.07 (dd, J=7.8, 0.6 Hz, 1H), 7.12 (td, J=7.5, 1.2 Hz, 1H), 7.36 (td, J=7.5, 0.9 Hz, 1H), 7.50 (td, J=5.7, 1.5 Hz, 1H), 7.70 (dd, J=7.8, 1.5 Hz, 1H), 8.02 (d, J=7.8, 1H), 8.12 (m, 3H), 10.13 (dd, J=6, 0.9 Hz, 1H); ¹⁹F NMR (376 MHz, CD₂Cl₂, 298 K): δ −64.77 (s,3F, p-CF₃), −61.43 (s,6F, o-CF₃).; elemental analysis (%) calcd for: C₂₀H₁₀AuF₉IN: C, 31.64; H, 1.33; N, 1.85; Found: C, 31.41; H, 1.26; N, 1.70.

cis-[(N̂C)AuLR₁] [N̂C=2-phenylpyridine (ppy), L=C₆H₃(CF₃)₃ (Fmes), R₁=Ethynylbenzene (Eben)] (109). To a Schlenk flask containing MeOH (15 mL) and Eben (60 mg, 0.344 mmol) under N₂ atmosphere AgOTf (0.106 g, 0.413 mmol) was added. H₂O (5 mL) was added with a syringe, whereas the solution turned immediately to a white suspension. The suspension was stirred for 30 minutes. The solvent was cannulated and the precipitate was washed with cooled MeOH (20 mL). The solvent was again cannulated and the precipitate was dried under vacuum to afford the ligand as a crude unpurified white powder.

To a Schlenk flask containing the cis-[(ppy)Au(Fmes)(Cl)] (34.5 mg, 0.052 mmol) dissolved in DCM (3 mL) under N₂ atmosphere, a Silver-Eben (21.8 mg, 0.104 mmol) suspension in MeOH (3 mL) was transferred with the cannula. The reaction was stirred for 6 h at room temperature. The reaction was then quenched with H₂O (20 mL), washed with a saturated NaCl-solution (20 mL) and extracted with DCM (2×20 mL). The organic layer was dried over MgSO₄, filtered and the solvent was removed under reduced pressure, to give the crude product as a brownish solid. The residue was purified by column chromatography on silica gel (eluent: HA/DCM=1.5/1) to afforded a white solid of the title compound. Single crystals suitable for X-ray diffraction analysis were obtained from slow evaporation by layering of pentane over concentrated solution of the complex in DCM at 0-5° C. Yield=11.5 mg, 0.016 mmol, 30%. ¹H NMR (500 MHz, CD₂Cl₂, 293 K): δ 6.38 (dd, J=7.5, 1 Hz, 1H), 7.13 (td, J=7.5, 1 Hz, 1H), 7.22 (m, 2H), 7.30 (td, J=8, 1.5 Hz, 1H), 7.33 (dd, J=8.5, 2 Hz, 2 H), 7.52 (td, J=7, 1 Hz, 1H), 7.76 (d, J=8 Hz, 1H), 7.98 (d, J=8 Hz, 1H), 8.13 (td, J=8, 1.5 Hz, 1H), 8.17 (s, 2H), 9.66 (dd, J=5.5, 1 Hz, 1H); ¹³C {¹H}NMR (125 MHz, CD₂Cl₂, 293 K): δ 103.60, 120.75,124.02, 124.65, 125.04, 126.24, 127.15, 127.46, 128.37, 131.75, 131.79, 134.23, 134.48, 134.66, 142.09, 145.74, 151.23, 158.20, 166.57.; ¹⁹F NMR (376 MHz, CD₂Cl₂, 298 K): δ −64.72 (s,3F, p-CF₃)., −62.60 (s,6F, o-CF₃); elemental analysis (%) calcd for: C₂₈H₁₅AuF₉N: C, 45.86; H, 2.06; N, 1.91; Found: C, 45.71; H, 2.29; N, 1.71.

cis-[(N̂C)AuLR₁] [N̂C=2-phenylpyridine (ppy), L=C₆H₃(CF₃)₃ (Fmes), R₁=N,N-diphenyl-4-1(trimethylsilyl)ethynyl (4-EDP)] (110). To a Schlenk flask containing an orange solution of MeOH (2 mL) and 4-EDP (50 mg, 0.146 mmol), AgOTf (0.075 g, 0.292 mmol) was added under N₂ atmosphere. H₂O (1 mL) was added with a syringe, whereas the solution turned immediately to an orange suspension. THF (1 mL) was added for a better solubility. The suspension was stirred for 2 days. The solvent was cannulated and the precipitate was washed with cooled MeOH (20 mL). The solvent was again cannulated and the precipitate was dried under vacuum to afford the ligand as crude unpurified orange powder. To a Young-Schlenk containing the cis-[(ppy)Au(Fmes)(Cl)] (34.5 mg, 0.052 mmol) dissolved in DCM (mL) under N₂ atmosphere, a Silver-4-EDP (80.8 mg, 0.215 mmol) suspension in MeOH (5 mL) was transferred with the cannula. The reaction was stirred for 2 days at 45° C. The reaction was then quenched with H₂O (20 mL), washed with a saturated NaCl-solution (20 mL) and extracted with DCM (2×20 mL). The organic layer was dried over MgSO₄, filtered and the solvent was removed under reduced pressure, to give the crude product as a brownish solid. After a pentane wash the residue was purified by column chromatography on silica gel (eluent: DCM/HA=0.75/1) to afforded a white solid of the title compound. Single crystals suitable for X-ray diffraction analysis were obtained from slow evaporation by layering of pentane over concentrated solution of the complex in DCM at 0-5° C. Yield=18.8 mg, 0.021 mmol, 19%. ¹H-NMR (500 MHz, CD₂Cl₂, 298 K): δ 6.39 (d, J=8.5 Hz, 1H), 6.90 (d, J=11 Hz, 2H), 7.03 (m, 6H), 7.13 (td, J=9, 1.5 Hz, 1H), 7.25 (m, 7H), 7.52 (td, J=7, 1.5 Hz, 1H), 7.76 (d, J=9 Hz, 1H), 8.00 (d, J=10Hz, 1H), 8.12 (td, J=10, 2 Hz, 1H), 8.17 (s, 2H), 9.68 (dd, J=7.5, 1.5 Hz, 1H); ¹⁹F NMR (376 MHz, CD₂Cl₂, 298 K): δ −64.71 (s,3F, p-CF₃), −62.59 (s,6F, o-CF₃).

TABLE 1
Photophysical properties of complexes 1-8

| | Room temperature solution (CH₂Cl₂) | | | | |
|---|---|---|---|---|---|
| | Absorption | | | | |
| | □max[nm] | | | | |
| | (□max/ | Emission | | | 77 K glass^{[b]} |
| Complex | [dm³mol⁻¹cm⁻¹]) | □max[nm] | □ [μs] | □P^{[a]} | (2-MeTHF) |
| 1 | 308 (5145), | 484, 506 | 1.10 | 3.7 × 10⁻³ | 478, 513, 540 |
| | 317 (5385) | | | | |
| 2 | 316 (8480) | 467 (sh), 490, | 0.33 | 9.5 × 10⁻³ | 453, 485, 512 |
| | | 519 (sh) | | | |
| 3 | 324 (7214), | 471 (sh), 493, | 4.41 | 1.0 × 10⁻³ | 457, 489, 528 |
| | 338 (5254, sh) | 529 (sh) | | | |
| 4 | 321 (8623) | 470 (sh), 490, | 1.23 | 9.9 × 10⁻³ | 452, 486, 517 |
| | | 522 (sh) | | | |
| 5 | 319 (7884) | 472 (sh), 492, | 0.53 | 1.9 × 10⁻² | 453, 489, 515 |
| | | 526 (sh) | | | |
| 6 | 287 (13700), | 537, 569 | 1.15 | 2.5 × 10⁻³ | 522, 541, 563 |
| | 357 (8070) | | | | |
| 7 | 286 (12610), | 544, 577 | 1.12 | 1.5 × 10⁻³ | 527, 545, 570 |
| | 363 (8540) | | | | |
| 8 | 294 (8810), | 548, 592 | 1.21 | 2.0 × 10⁻³ | 548, 593 |
| | 380 (5760) | | | | |

^{[a]}Photoluminescence quantum yield determined with quinine sulfate as standard at 298 K.
^{[b]}Vibronic structured emission bands

TABLE 2
Photophysical properties of complexes 101-110

| | Absorption | Emission | | |
|---|---|---|---|---|
| | λₘₐₓ (nm) | λₘₐₓ (nm) | τ (μs) | 77 K glass^{a} |
| Complex | (298 K) | (298 K) | (298 K) | (2-me-THF; nm) |
| 101 | 332 | 499 | 0.59 | 457, 491, 521 |
| 102 | 375 | 583 | 0.78 | 484, 527, 569 |
| 103 | 391 | 608 | 0.94 | 583, 594, 602 |
| 104 | 318 | 488 | 0.49 | 452, 485, 513 |
| 105 | 373 | 497 | 0.53 | 464, 472, 497 |
| 106 | 368 | 588 | 0.93 | 537, 582, 636 |
| 107 | 323 | 493 | 2.25 | 454, 478, 523 |
| 108 | 310 | 488 | 2.32 | 453, 486 |
| 109 | 316 | 490 | 2.23 | 454, 484, 516 |
| 110 | 325 | 610 | 2.54 | 421, 464, 485 |

^{a}Vibronic structured emission bands.

### REFERENCES

(1) Highly efficient OLEDs with Phosphorescent Materials; Yersin, H., Ed.; Wiley-VCH: Weinheim, 2008.

(2) Wong, K. M.-C.; Hung, L.-L.; Lam, W. H.; Zhu, N. Y.; Yam, V. W.-W. J. Am. Chem. Soc. 2007, 129, 4350.

(3) Wong, K. M.-C.; Zhu, X. L.; Hung, L.-L.; Zhu, N. Y.; Yam, V. W.-W.; Kwok, H.-S. Chem. Commun. 2005, 2906.

(4) Yam, V. W.-W.; Wong, K. M.-C.; Hung, L.-L.; Zhu, N. Y. Angew. Chem. Int. Edit., 2005, 44, 3107.

(5) Yam, W.-W. Y.; Wong, M.-C.; Kwok, H.-S.; Zhu, X.; Organization, W. I. P., Ed. United states, 2006.

(6) Vicente, J.; Bermudez, M. D.; Carrión, F. J.; Jones, P. G. Chem. Ber. 1996, 129, 1301.

(7) Vicente, J.; Bermudez, M. D.; Carrión, F. J.; Jones, P. G. Chem. Ber. 1996, 129, 1395.

(8) Schuster, O.; Schmidbaur, H. Organometallics 2005, 24, 2289.

(9) Mendez, L. A.; Jimenez, J.; Cerrada, E.; Mohr, F.; Laguna, M. J. Am. Chem. Soc. 2005, 127, 852.

(10) Garg, J. A.; Blacque, 0.; Venkatesan, K. Inorg. Chem. 2011, 50, 5430.

(11) Au, V. K.-M.; Wong, K. M.-C.; Zhu, N. Y.; Yam, V. W.-W. Chem.—Eur. J. 2011, 17, 130.

### Concluding Remarks

1) A process for the preparation of monocyclometalated Au(III) complexes, cis-[(N̂C)AuL₁L₂] and cis-[(N̂C)AuL₁AL₂] represented by generic chemical formulae 1a and 1b respectively with ligands L₁ and L₂ being either similar (L₁=L₂) or dissimilar (L₁≠L₂) but with at least one of either (L₁ or L₂) comprising a σ-donating carbanionic group is described here. L₃ as represented in formula 1c denotes a neutral donor ligand bound in a tridentate fashion. The complexes depicted by the formulae 1a, 1b and 1c in the present invention are suitable as emissive phosphorescent organometallic materials in OLEDs.

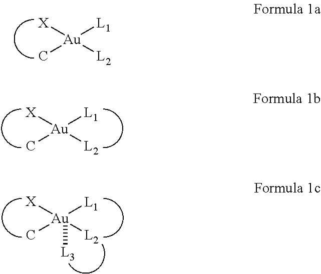

2) The core structure comprises of mono-cyclometalated bidentate chelating ligand with one carbanionic donor and one neutral donor and ancillary ligands L₁ and L₂ disposed cis to each other. The cyclometalated part of the formula (1a and 1b) represented as ĈX, consists of a group with an atom capable of dative bonding (X), preferably nitrogen or carbenic C, to the metal and can independently be selected as a part of the substituted or unsubstituted aromatic or heteroaromatic systems. The other part (C) being mono-carbanionic ligand as a part of substituted or unsubstituted aromatic or heteroaromatic systems. Both the entities C and X are linked to each other by covalent bonding as a part of conjugated aromatic or non-aromatic systems.

3) The description for the process of preparation of the entities (Formulae 1a and 2a) from their corresponding Au(III) dihalide precursor complex of the formula cis-[(N̂C)AX₂] wherein X=halogens, can further be sub-classified based on the nature of L₁ and L₂ as (i) Substitution by means of lithiation for systems where the carbanion is derived from sp²-hybridised centre, for example, as in aromatic aryl or heteroaromatic systems. (ii) Substitution by means of Cu(I) promoted metathesis, in the case where the carbanion is derived from sp-hybridised centre, for example as in terminal alkynes. (ii) Substitution by means of anionic it-accepting ligands like cyanide anion. All of these transformations are achieved by deprotonation (formal removal of hydrogen atom) in the presence of bases in organic solvents. The preferred stoichiometry and reaction conditions for each of the above are described in the present invention.

1. An organometallic gold compound according to Formula (1a) or (1b) or (1c) 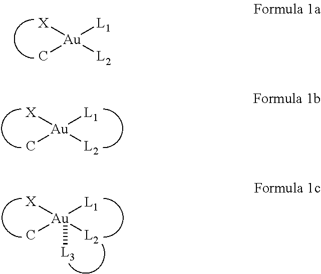
wherein Au is gold in its oxidation state 3+, with ligands L₁ and L₂ being either identical (L₁=L₂) or different (L₁≠L₂), with at least one of either (L₁ or L₂) comprising a σ-donating carbanionic group, which ligands L₁ and L₂ chelate to Au either in a monodentate fashion (Formula 1a) or in a bidentate fashion (Formula 1b), and with L₃ as represented in formula 1c denoting a neutral donor ligand bound in a tridentate fashion, the compound further having a cyclometallated ligand part ĈX comprising a ligand atom (X) capable of dative bonding and a monocarbanionic ligand atom (C), the two ligand atoms (X) and (C) being linked to each other by covalent bonding as a part of a conjugated aromatic or non-aromatic system, with the provision that L₁ and L₂ are not both an alkynyl containing group.

2. An The organometallic gold compound according to claim 1, wherein said ligands (L₁) (L₂) and (L₃) are each, independently, a group containing halogen, hydrogen, cyano, amino, nitro, aryl, alkoxy, alkynyl, heteroaryl, heteroalkynyl, alkylcarbonyl, arylcarbonyl, alkoxycarbonyl, mono- or diaminocarbonyl, heteroaryl, heteroalkynyl, alkylcarbonyloxy, arylcarbonyloxy.

3. The organometallic gold compound according to claim 1, wherein said ligand atom (X) is nitrogen or a carbenic C or phosphorus P or sulfur S and wherein said monocarbanionic ligand atom (C) is a part of a substituted or non-substituted aromatic or heteroaromatic system.

4. The organometallic gold compound according to claim 1, selected from the group consisting of following Compounds 1, 2, 3, 4, 5, 6, 7 and 8:

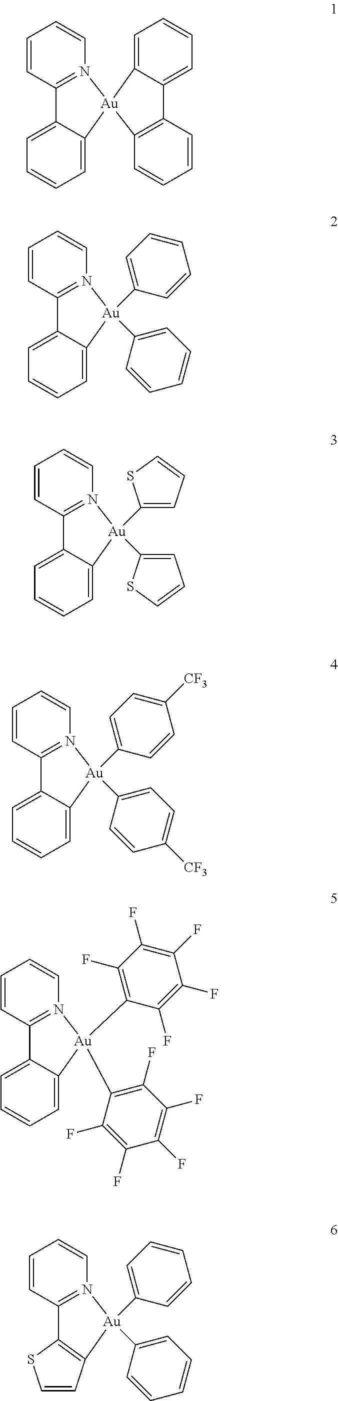

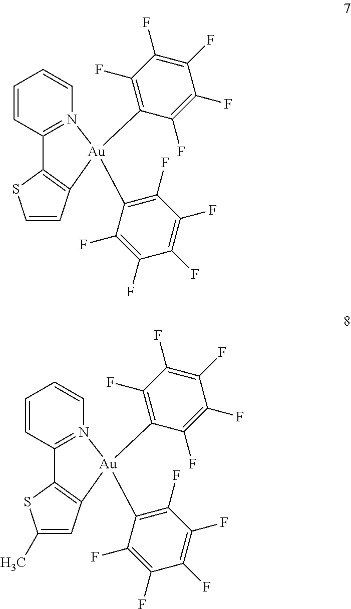

5. The organometallic gold compound according to claim 1, selected from the group consisting of following Compounds 104, 105, 106 and 108:

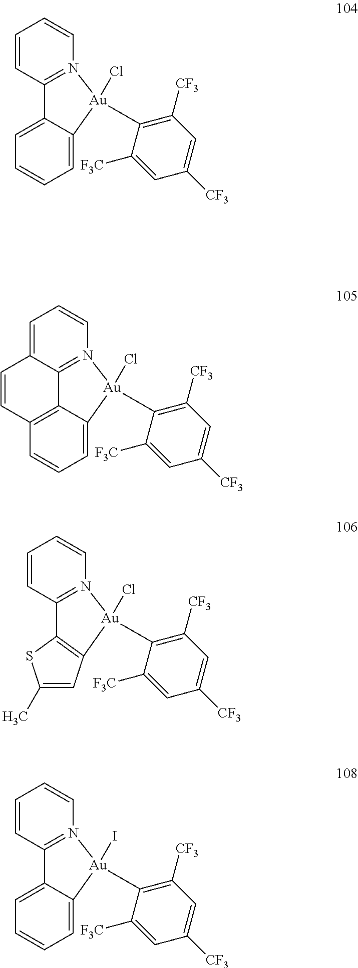

6. The organometallic gold compound according to claim 1, selected from the group consisting of following Compounds 101, 102, 103 and 107:

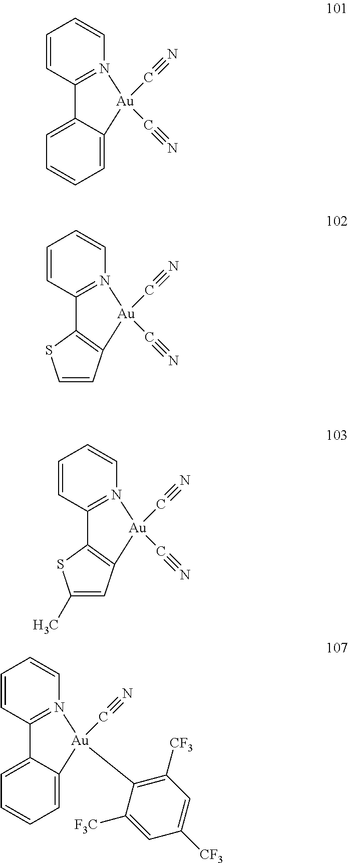

7. The organometallic gold compound according to claim 1, selected from the group consisting of following Compounds 109 and 110:

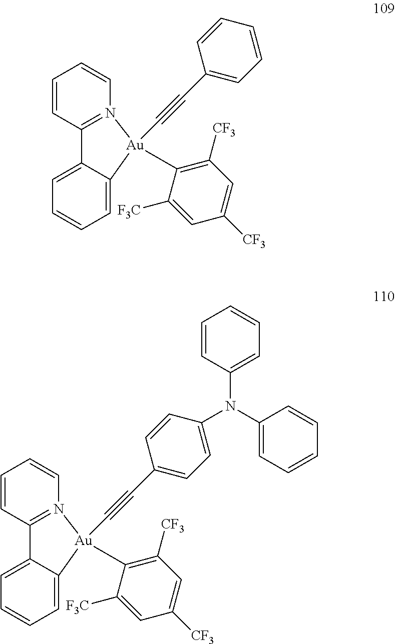

8. A method of preparing a compound according to claim 1, comprising reaction steps as defined in the description.

9. Use of a compound according to claim 1 in an electroluminescent device.

10. An electroluminescent device comprising a compound according to claim 1.
